(19) United States
(12) Patent Application Publication
(10) Pub. No.: US 2023/0376850 A1
(43) Pub. Date: Nov. 23, 2023

(54) METHOD AND DEVICE FOR RECONSTRUCTING A POSITION OF SEMICONDUCTOR DEVICES ON A WAFER

(71) Applicant: Robert Bosch GmbH, Stuttgart (DE)

(72) Inventors: Andreas Steimer, Schoemberg (DE); Frank Schmidt, Leonberg (DE)

(21) Appl. No.: 18/318,911

(22) Filed: May 17, 2023

(30) Foreign Application Priority Data
May 23, 2022 (DE) 10 2022 205 141.6

(51) Int. Cl. G06N 20/00

(52) U.S. Cl. CPC G06N 20/00

(57) ABSTRACT

A method for ascertaining an assignment rule in order to merge test results from different tests of the same semiconductor device. The method includes the following steps: adapting a model, e.g., a linear regression model, using the model to predict the test data; calculating costs based on the predictions; using a gradient descent method to minimize the costs.

### CROSS REFERENCE

The present application claims the benefit under 35 U.S.C. § 119 of German Patent Application No. DE 10 2022 205 141.6 filed on May 23, 2022, which is expressly incorporated herein by reference in its entirety.

### FIELD

The present invention relates to a method for reconstructing the positions of semiconductor devices on a wafer on which they were applied, after the semiconductor components have been cut out of the wafer; the present invention furthermore relates to a method which is designed to execute the method.

### BACKGROUND INFORMATION

During the packaging process of semiconductor devices (especially of power MOS), the retraceability of the semiconductor devices to their original wafers and to their original position on the wafer is lost. This specifically means that the position of each semiconductor device on a wafer is no longer available as soon as the wafer has been cut up or diced (i.e., ‘diced’ being a method in which the semiconductor component is separated from the wafer) and packaged. Suppliers of packaging processes are able to offer at least a rough match between loose semiconductor devices in the final test (the checking process of the semiconductor devices following the packaging) and semiconductor devices on the wafer in the wafer-level tests (i.e., the testing process preceding the packaging). However, this still leads to several thousands of semiconductor devices that are unassignable to multiple wafers. Since this basically involves a combinatory problem, the complexity of solving the task is factorial because there are n-factorially different possibilities of positioning the semiconductor devices in such a way that they correspond to the correct sequence, n being the number of semiconductor devices.

For the reconstruction of the positions of semiconductor devices, German Patent Application No. DE 10 2021 209 343 provides for an alternating optimization of a regression model for predicting test data and an assignment rule, the reconstruction subsequently being realizable based on the optimized assignment rule.

### SUMMARY

The present invention may offer the advantage of making it possible to ascertain a potential assignment between semiconductor devices as a function of results of the wafer-level test and packaged semiconductor devices as a function of the results of the final test, and managing to do so without retroactively added metadata such as unique identifiers, etc.

In addition, the present invention may have the advantage that it allows for the use of a gradient descent method and thus is better able to be scaled for a larger number of semiconductor devices in comparison with the related art, and that through the steps of the gradient descent, it always reliably converges in the direction of a solution in each gradient descent step. In other words, the present invention is able to ascertain an assignment of the results for a larger number of semiconductor devices, in particular in a more efficient manner and with limited computer resources.

Additional aspects of the present invention are disclosed herein. Advantageous refinements of the present invention are disclosed herein.

In a first aspect, the present invention relates to an in particular computer-implemented method for ascertaining an assignment rule. According to an example embodiment of the present invention, the assignment rule assigns variables from a first set of first variables to variables from a second set of second variables. A set may be understood as a form of combined elements such as the individual variables, for example. The first and second set are preferably different sets that include no shared variable. An index is preferably assigned to the variables of the first and second set. All indices of the first and second sets may be understood as index sets, that is, as a set whose elements index the variables of the first or second set in an orderly fashion in each case. The assignment rule then assigns an index from the second index set to the first index set. The assignment rule thus describes which first variable belongs to which second variable and preferably also the other way around. The assignment rule may be available in the form of a list or table or, preferably, a matrix.

According to an example embodiment of the present invention, the method begins with an initialization of the assignment rule and a provision of the first and second set. The initial assignment rule is able to be randomly selected or selected as an identity assignment. Other initial assignment rules are possible as an alternative, e.g., a predefined, already partly correct assignment. The initialization preferably takes place at random, in particular with a randomly selected bistochastic matrix of the Birkhoff polytope, or a matrix that corresponds to a random permutation matrix is selected as an initial assignment rule. It should be noted that bistochastic matrices as assignment rules generally describe a “soft” assignment, which means that this assignment may also be considered a probabilistic assignment.

Next, a repeated execution of the steps a)-d) described in the following text takes place. The repetitions are able to be carried out for a predefined number of maximum repetitions, or an abort criterion can be defined, the repetition being stopped when the abort criterion has been satisfied. The abort criterion, for example, is a min. change in the assignment rule.
a) Preparing a dataset which includes the first variables and their second variables assigned according to the assignment rule in each case. The dataset may also be called a training dataset, in which the assigned second variables are so-called ‘labels’ of the first variables. It should be noted that this step may be optional because the following steps that use this dataset in essence require only the information of the current assignment rule between the first and second variables, which is able to be provided either by the dataset or by a current assignment rule. The current assignment rule is the assignment rule that is available for the current repetition of steps a)-d), or in other words, the particular assignment rule which was used during the execution of the most recent step a).
b) Training a machine-learning system so that the machine learning system ascertains the respective assigned second variables of the dataset as a function of the first variables in each case. Training may be understood as an adaptation of parameters of the machine learning system in such a way that predictions of the machine learning system ascertained by the system lie as close as possible to the second variables (‘labels’) of the dataset. The optimization may be implemented with regard to a first cost function. The first cost function preferably characterizes a math. difference between the outputs of the machine learning system and the labels. The optimization is preferably carried out with the aid of a gradient descent method or other conventional training methods for machine learning systems. The machine learning system may be one or a plurality of decision tree(s), a neural network, a support vector machine, a regression model, or something similar. The training can be carried out until a further improvement of the machine learning system during the training is negligibly low, that is, satisfies a second abort criterion.
c) Ascertaining a second cost function, the second cost function characterizing distances between predictions of the machine learning system as a function of the first variables and the second variables that are assigned to the respective first variables according to the assignment rule in each case. The distance is able to be ascertained using an L2 norm. Other distance measures are also possible.
d) Optimizing the assignment rule with regard to the second cost function so that an assignment of the first variables to the second variables according to the assignment rule minimizes the second cost function. To this end, a gradient of the second cost function with regard to the assignment rule is ascertained, and the gradient is then projected onto a convex unit polytope, which includes a set of all possible assignment rules. Next, the assignment rule is modified as a function of the projected gradient. The modification of the assignment rule as a function of the projected gradient is able to be carried out in the conventional manner of the gradient descent method, for instance by subtracting the projected gradient from the current assignment rule.

It is provided to carry out the projection of the gradients using a Boyle-Dykstra projection algorithm, see also Boyle, J. P.; Dykstra, R. L. (1986); “A method for finding projections onto the intersection of convex sets in Hilbert spaces;” Lecture Notes in Statistics. Vol. 37. pp. 28-47. doi:10.1007/978-1-4613-9940-7_3. ISBN 978-0-387-96419-5, or Takouda, “Un problème d'approximation matricielle: quelle est la matrice bistochastique la plus proche d'une matrice donnée,” RAIRO Operations Research 39 (2005), 35-54. https: //doi.org/10.1051/ro:2005003. As an alternative, the following algorithm is able to be used: Gaffke, N.; Mathar, R. (1989). “A cyclic projection algorithm via duality”. Metrika. 36: 29-54. doi:10.1007/bf02614077 or a Sinkhorn algorithm such as described in the paper Wang, Fei, Ping Li, and Arnd Christian Konig. “Learning a bi-stochastic data similarity matrix.” 2010 IEEE International Conference on Data Mining. IEEE.

It is furthermore provided that the assignment rule be a doubly stochastic matrix. In other words, the assignment rule is a relaxed permutation matrix which has continuous values. In addition, it is provided that the unit polytope be a Birkhoff polytope. The Birkhoff polytope is a polytope which includes all doubly stochastic matrices and thus a strict superset of permutation matrices.

The relaxed permutation matrix offers the advantage that it allows for a direct application of the gradient descent method so that the above-mentioned characteristics of a scalability and convergence are able to be achieved.

The assignment rule ascertained in the last repetition of step d) is a final assignment rule, which is output in an optional step.

If a unique assignment rule is required, a method for ascertaining a true permutation matrix as a function of the output assignment rule is provided in a second aspect of the present invention. A (true) permutation matrix may be understood as a matrix in which precisely one entry is one and all other entries are zero in each line and each column. For the second aspect of the present invention, it is provided that a direction in the Birkhoff polytope in which the second cost function essentially does not change is ascertained for the output assignment rule, the assignment rule being mapped along the ascertained direction onto a facet of the Birkhoff polytope situated in this direction. The direction is able to be determined using conventional weighted linear combinations of gradients. For example, a first gradient can be calculated with regard to a distance from the current assignment rule in the Birkhoff polytope to the facets/corner points of the Birkhoff polytope, and a second gradient can be calculated with regard to the second cost function. The second gradient, weighted by the first and second gradient, is then subtracted from the second gradient, and the assignment rule is mapped along the direction obtained after the subtraction.

The two steps of ascertaining the direction and mapping are repeated multiple times until a vertex of the Birkhoff polytope is reached, that is, a 0-dimensional area that corresponds to a permutation matrix, this permutation matrix of the vertex being output as an assignment rule. The permutation matrix as an assignment rule then unambiguously assigns the first variables to the second variables, which means that, at most, the assignment rule assigns a second variable to each first variable, and preferably also the other way around.

It is advantageous in this context that there may be applications in which a unique assignment rule is required, and a unique assignment rule is discovered based on this procedure that provides equally satisfactory solutions in the sense of the second cost function to the optimal output assignment rule.

According to an example embodiment of the present invention, it is provided that the machine learning system is a regression model, which ascertains the second variables as a function of the first variables and parameters of the regression model, the parameters of the regression model being adapted during the training. In general, the regression is used to model relationships between a dependent (often also an explanatory variable) and one or more independent variable(s) (often also explanatory variables). The regression is able to parameterize a more complex function so that it optimally represents these data according to a specific mathematical criterion. For example, the usual least squares method calculates an unambiguous straight line (or hyperplane) which minimizes the sum of the deviation squares between the true data and this line (or hyperplane), that is, the residual square sum. Conventional methods for regression models may be used to train the regression model. The variables may be scalars or vectors such as a time series, in particular of sensor data acquired or ascertained indirectly by a sensor. The first and second variables preferably are one or a plurality of measuring result(s) from a measurement or from a plurality of different measurements which were carried out on an object from a plurality of objects in each case. In other words, each variable is assigned to one of the objects. In the step of preparing the dataset, it is also possible to use for the second variables only a predefinable number of the measuring results of the plurality of measuring results. The assignment rule may indicate which first and second variables are measuring results of the same object. Especially preferably, the at least one measurement of the objects for the first variables was carried out at a first point in time, and the measurement for the second variable is carried out at a second point in time, the second point in time being later than the first point in time. The second point in time may be given after the objects were subjected to a modification or change.

In addition, according to an example embodiment of the present invention, it is provided that the first and second variables characterize a product during its production following different production process steps. Here, for example, the second point in time may be given when a production process step has been concluded. The product may be any product produced in a production facility. During the production of the product, the retraceability with regard to the preceding process steps is lost (so-called bulk goods), for instance if it is no longer possible to directly assign the product from the bulk goods, e.g., screws, to a production batch. The first variables may possibly characterize components, in particular parts, and the second variables characterize final products, the assignment rule describing which components were processed into which product or which component was installed in which product, for instance if the component in the product can no longer be removed for reading out a serial number without destroying the product. With the aid of the present invention, it is then possible to assign the production batch of the component based on measurements of the product.

According to an example embodiment of the present invention, the first and second variables may be measuring/test results or other kinds of characteristics of the products, components, etc. The first and second variables preferably differ slightly from one another, for example as a result of production tolerances, but they describe the same measurements/properties of the products, components, etc.

In addition, according to an example embodiment of the present invention, it is provided that the first variables are first test results or measuring results of semiconductor device elements on a wafer, and the second variables are second test results or measuring results of the semiconductor device elements after they have been cut out of the wafer. Semiconductor device elements may be parts of grown electric components on the wafer, e.g., a transistor group of an integrated circuit. The test results may also relate to the entire semiconductor device. For the machine learning system, the linear regression has shown to be particularly effective for finding the best assignment rule. This is because it assumes a linear relationship, which in this case is a meaningful assumption for an assignment of the test results. The linear regression is a special case of regression. In the linear regression, a linear function is assumed. In other words, only relationships in which the dependent variable is a linear combination of the regression coefficients (but not necessarily of the independent variable) are used.

In addition, according to an example embodiment of the present invention, it is provided that the first test results are wafer-level test results, and the second test results are final test results. Preferably, there are fewer final test results than wafer-level test results. The tests are voltage tests and/or contacting tests, for instance.

In addition, according to an example embodiment of the present invention, it is provided that the semiconductor device elements were produced on a plurality of different wafers. This is so because it has been shown that the method is able to find a correct assignment rule within a reasonable computing time even across multiple wafers.

According to an example embodiment of the present invention, it is furthermore provided to ascertain which second test result belongs to which first test result as a function of the assignment rule, and it is then ascertained as a function of the associated first test result at which position the semiconductor device was situated within the wafer. This allows for a position reconstruction which, for the first time, makes it possible to unambiguously retrace the semiconductor devices from the last production process steps of the semiconductor production to preceding process steps.

Apart from the positions, according to an example embodiment of the present invention, it is furthermore provided that additional variables which characterize the wafer and/or the semiconductor devices on the wafer and assigned test results be ascertained in each case, these data being combined to form a further training dataset, and a further machine learning system being trained to predict the second test results as a function of the further training dataset.

This may offer the advantage that the assignment may be used to prepare a further training dataset for training a further machine learning system to predict properties of a packaged semiconductor device element at an earlier stage in the production process. This considerably shortens the time until deviations in the process parameters are detected, in particular for parameters that can be correctly evaluated only during final tests (e.g., RDSon).

In this context, according to an example embodiment of the present invention, it is furthermore advantageous that the assignment is also able to be used to train a further machine learning system which actively identifies defective semiconductor chips. This saves process resources and reduces waste.

In further aspects, the present invention relates to a device and a computer program, each being designed to execute the above methods, and to a machine-readable memory medium on which this computer program is stored.

In the following text, embodiments of the present invention will be described in greater detail with reference to the figures.

### BRIEF DESCRIPTION OF THE DRAWINGS

FIG. 1 shows schematically a packaging process.

FIG. 2 shows schematically an exemplary embodiment of a flow diagram of the present invention.

FIG. 3 shows schematically a training device according to an example embodiment of the present invention.

### DETAILED DESCRIPTION OF EXAMPLE EMBODIMENTS

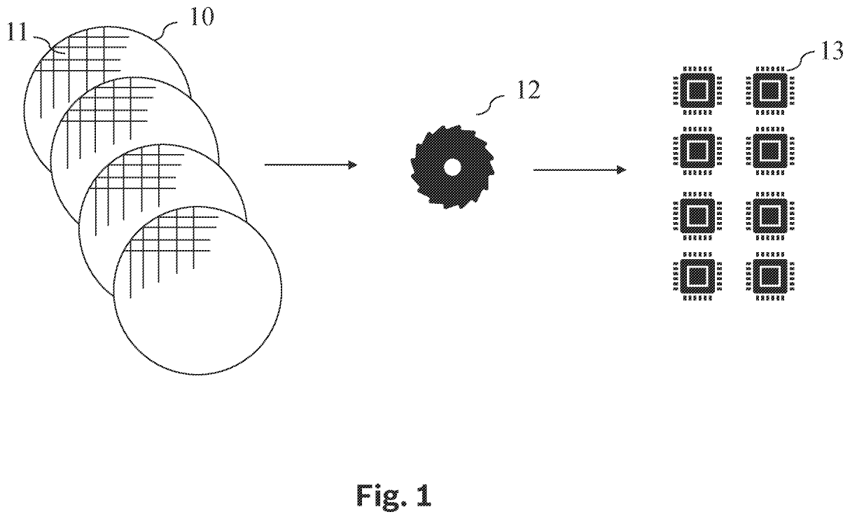

In the packaging process of semiconductor devices or semiconductor device elements, the retraceability of the devices to their original wafers and to their original position on the individual wafer is usually lost. This is so because the individual semiconductor device elements may be intermixed after the semiconductor devices have been cut out, so that without a unique marking of the parts, their position on the wafer is lost. This is schematically illustrated in FIG. 1. Wafers 10 have a plurality of semiconductor elements or semiconductor devices 11 in each case. At this point, each semiconductor device 11 has a known position on wafers 10. As a rule, semiconductor devices 11 are subjected to various tests at this stage, which are also referred to as wafer-level tests. In the next step, wafers 10 are cut up so that semiconductor devices 11 become separated from each other. The cutting can be done using a saw 12 or using a laser. Finally, the cut semiconductor devices are packaged, e.g., installed in microcontroller 13. At this stage at the very latest, the information indicating on which wafer 10 and in which position within wafer 10 the semiconductor device was originally positioned has been lost. Microcontrollers 13 including semiconductor devices 11 are subjected to a multiplicity of tests again, which are also known as final tests. However, since intermixing has occurred because wafers 10 have been cut up, it is not easily possible to unambiguous trace back wafer 10 on which the individual semiconductor devices of microcontrollers 13 were situated and which wafer-level test corresponds to which final test, that is to say, are the test results of the same semiconductor device. The semiconductor devices may be microelectronic subassemblies such as integrated circuits (hereinafter also referred to as chip), sensors or similar things.

One object of the present invention is to reestablish the retraceability after the packaging process in a semiconductor production process. Such an assignment provides further contributions such as a better process control or early predictions of final chip characteristics. In addition, the cause analysis of the deviations measured in the final test at the chip level is able to be expanded to the processes in the wafer production. This in turn provides a much deeper understanding of the processes and leads to a better process control and thus to a better quality.

An assignment algorithm is provided, which is made up of an alternating sequence of optimizing regression parameters (during the regression from the wafer-level test to the test data of the final test) and a subsequent optimization of the assignment of test partners. The current assignment of the final test chips is used as a ‘regression label’ in each iteration.

Moreover, the present invention uses a cost-minimizing algorithm, which is able to ascertain an optimal assignment under a predefined cost function. In one embodiment, a suitable distance measure (e.g., an L2 norm) between the final test prediction of a trained regressor and the regression label is used as a cost function. On the basis of this cost function, the algorithm ascertains a change in the assignment so that the regression loss is minimized. Depending on the characteristics of the data, the regressor or regression model is freely selectable (e.g., a linear regression for linear dependencies).

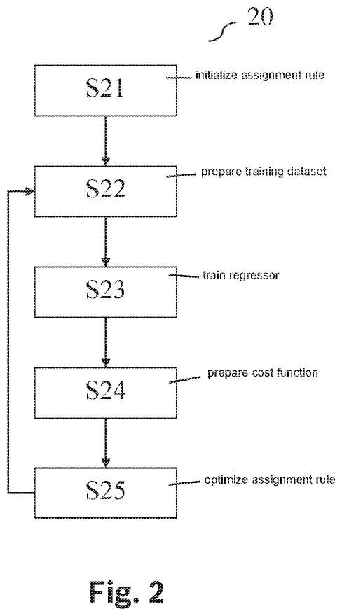

FIG. 2 schematically shows a flow diagram 20 of a method for ascertaining an assignment rule that assigns the test results of the final test to the corresponding test results of the wafer-level test. After the conclusion of the method, an assignment rule which assigns the matching test results of the wafer-level test to the final tests is to be available. In other words, it describes test results that belong to one another and originate from the same semiconductor component.

The method begins with a step S21. In this step, the assignment rule is initialized. The assignment rule is preferably initialized as a doubly stochastic matrix, but it is possible as an alternative to use a random permutation matrix or an identity matrix for the initialization. In addition, the test results of the wafer-level test (WLT) and final test (FT) are provided in this step.

Step S22 follows next. In this step, a training dataset is prepared which includes the WLT test results and their FT test results assigned according to the assignment rule.

After step S22 has been concluded, step S23 follows. In this step, a regressor f is trained so that the regressor ascertains the individually assigned final tests as a function of the wafer-level tests (WLT) according to the training dataset: f(WLT)=FT. Regressor f may be a linear regression model. The training of the regressor is carried out in the conventional manner such as via a minimization of a regression error on the training dataset by an adaptation of parameters of regressor f. After the regressor has been trained, step S24 is carried out. A cost function is prepared in this step. For example, the cost function is an L2 norm between the prediction of the regressor as a function of the corresponding WFT test result and as a function of the corresponding FT test results according to the assignment rule.

The cost function may be given as follows:

$$ϕ ( π , θ ) = \frac{1}{2} ‖ {f}_{θ} ( WLT ) - π \cdot$$

FT∥², where π is the assignment rule in the matrix notation. If the data include a lot of noise, a regularization term is able to be added to cost function ϕ. The regularization term preferably characterizes an entropy.

After step S24 has been concluded, the assignment rule is optimized in step S25. The optimization is accomplished by applying a gradient descent method to the cost function with the goal of obtaining an improved assignment rule. A gradient of the cost function with regard to the entries of the assignment rule is ascertained for this purpose. It should be noted that the parameterization of regression model f remains unchanged. To ensure that the assignment rule describes valid assignments, the gradient is projected onto the Birkhoff polytope. The Boyle-Dykstra algorithm is preferably used for this projection, see, for example, Takouda, “Un problème d'approximation matricielle: quelle est la matrice bistochastique la plus proche d'une matrice donnée,” RAIRO Operations Research 39 (2005), 35-54. https: //doi.org/10.1051/ro:2005003.

A gradient descent step is preferably carried out, whereupon the repetition is started again at step S22.

If an abort criterion is not satisfied, then the steps S21 to S25 are carried out anew. The abort criterion may be a predefined number of max. repetitions.

If the abort criterion is satisfied, then the method is concluded, and the assignment rule may be output.

Optionally, the output assignment rule is able to be converted into a unique one-to-one assignment rule. To this end, the output assignment rule, which lies within the Birkhoff polytope, may be moved to a corner point, the movement taking place under the following condition: ϕ((1−t)·π*+t·\hat{π})=0 ∀0≤t≤1. π* is the output assignment rule, and \hat{π} is a permutation matrix. For practical purposes, permutation matrix \hat{π} may be found in such a way that a search takes place for a direction along which ϕ remains closest to zero, this direction then being followed until an edge (i.e., a facet) of the Birkhoff polytope is reached. There, this process is repeated, the dimensionality of the area being successively reduced in this way until a vertex, i.e., a 0-dimensional area which corresponds to a permutation matrix, has been reached.

In a step that optionally follows step S25, the position of semiconductor devices 11 on wafer 10 is reconstructed with the aid of the assignment rule. In the process, based on the assignment rule and starting with the FT test results, the WLT test results are able to be determined in reverse. Since in addition to the WLT test results, the position within the wafer where the respective test was carried out is normally stored as well, it is therefore possible to precisely reconstruct where on the wafer the corresponding semiconductor device was produced. After step S25, it is possible that a control signal for controlling a physical system such as a computer-controlled machine, e.g., a production machine, especially processing machines for the wafers, is actuated as a function of a position reconstruction. For example, if the FT test results are not optimal, the control signal is able to adapt a preceding production step appropriately so that better FT test results are obtained subsequently.

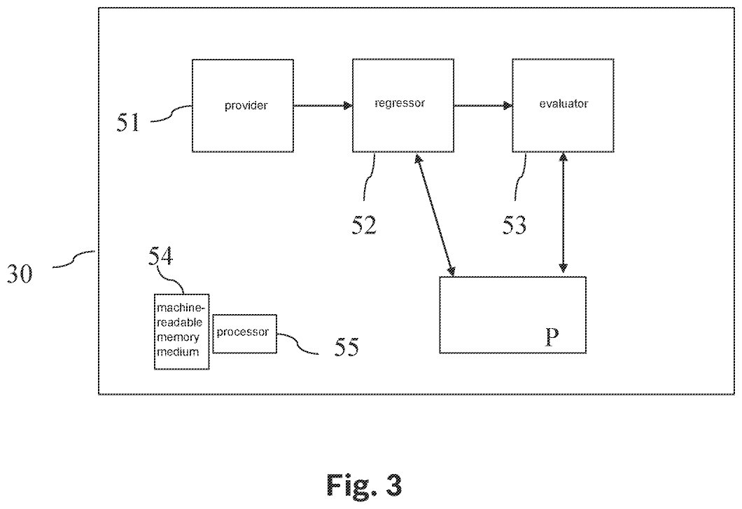

FIG. 3 schematically shows a device 30 for executing the method according to FIG. 2.

The device includes a provider 51, which provides the training dataset according to step S22. The training data are then conveyed to regressor 52, which uses the data to ascertain output variables. Output variables and training data are forwarded to an evaluator 53, which ascertains updated parameters of regressor 52 with their aid, which are transmitted to parameter memory P where they replace the current parameters. Evaluator 53 is designed to execute step S23.

The steps executed by device 30 may be stored, implemented as a computer program, on a machine-readable memory medium 54 and be executed by a processor 55.

The term ‘computer’ encompasses any devices for processing predefinable computing rules. These computing rules may be provided in the form of software or in the form of hardware, or also in a mixed form of software and hardware.

What is claimed is:

1. A method for ascertaining an assignment rule that assigns first variables from a first set of first variables to second variables from a second set of second variables, the method comprising the following steps:
initializing the assignment rule and providing the first and second set;
repeatedly executing the following steps a)-c):
a) training a machine learning system in such a way that the machine learning system ascertains the second variables assigned according to the assignment rule as a function of the first variables in each case;
b) ascertaining a cost function, the cost function characterizing distances between predictions of the machine learning system as a function of the first variables and the second variables that are assigned to the first variables according to the assignment rule; and
c) optimizing the assignment rule as a function of the cost function so that an assignment of the first variables to the second variables according to the assignment rule minimizes the cost function,
wherein in the step of optimizing, a gradient of the cost function with regard to the assignment rule is ascertained and the gradient is projected onto a unit polytope, which includes a set of possible assignment rules, and the assignment rule is modified as a function of the projected gradient.

2. The method as recited in claim 1, wherein the projecting of the gradient is carried out using a Boyle-Dykstra projection algorithm or a Sinkhorn algorithm.

3. The method as recited in claim 1, wherein the assignment rule is a doubly stochastic matrix, and the unit polytope is a Birkhoff polytope.

4. The method as recited in claim 3, wherein an optimized assignment rule is mapped to a true permutation matrix at a conclusion of the repetitions of the steps a) to c).

5. The method as recited in claim 4, wherein for the optimized assignment rule, a direction in the Birkhoff polytope is ascertained in which the cost function does not change, the assignment rule being mapped along the ascertained direction to a facet of the Birkhoff polytope, and the ascertaining of the direction and the mapping are repeated multiple times until a vertex of the Birkhoff polytope that corresponds to a permutation matrix is reached, the permutation matrix of the vertex being output as an assignment rule.

6. The method as recited in claim 1, wherein the first and second variables characterize products during their production following different production process steps, and the assignment rule characterizes which of the variables of the first and second set characterize the same product.

7. The method as recited in claim 1, wherein the first variables are first test results from semiconductor device elements on a wafer, and the second variables are second test results of the semiconductor device elements after they have been cut out of the wafer, and the assignment rule characterizes which first and second test results originate from the same semiconductor device element.

8. A device configured to ascertain an assignment rule that assigns first variables from a first set of first variables to second variables from a second set of second variables, the device configured to:
initialize the assignment rule and providing the first and second set;
repeatedly execute the following steps a)-c):
a) training a machine learning system in such a way that the machine learning system ascertains the second variables assigned according to the assignment rule as a function of the first variables in each case;
b) ascertaining a cost function, the cost function characterizing distances between predictions of the machine learning system as a function of the first variables and the second variables that are assigned to the first variables according to the assignment rule; and
c) optimizing the assignment rule as a function of the cost function so that an assignment of the first variables to the second variables according to the assignment rule minimizes the cost function,
wherein in the step of optimizing, a gradient of the cost function with regard to the assignment rule is ascertained and the gradient is projected onto a unit polytope, which includes a set of possible assignment rules, and the assignment rule is modified as a function of the projected gradient.

9. A non-transitory machine-readable memory medium on which is stored a computer program for ascertaining an assignment rule that assigns first variables from a first set of first variables to second variables from a second set of second variables, the computer program, when executed by a computer, causing the computer to perform the following steps:
initializing the assignment rule and providing the first and second set;
repeatedly executing the following steps a)-c):
a) training a machine learning system in such a way that the machine learning system ascertains the second variables assigned according to the assignment rule as a function of the first variables in each case;
b) ascertaining a cost function, the cost function characterizing distances between predictions of the machine learning system as a function of the first variables and the second variables that are assigned to the first variables according to the assignment rule; and
c) optimizing the assignment rule as a function of the cost function so that an assignment of the first variables to the second variables according to the assignment rule minimizes the cost function,
wherein in the step of optimizing, a gradient of the cost function with regard to the assignment rule is ascertained and the gradient is projected onto a unit polytope, which includes a set of possible assignment rules, and the assignment rule is modified as a function of the projected gradient.
